(19) United States
(12) Patent Application Publication
(10) Pub. No.: US 2012/0108081 A1
(43) Pub. Date: May 3, 2012

(54) APPARATUS HAVING IMPROVED SUBSTRATE TEMPERATURE UNIFORMITY USING DIRECT HEATING METHODS

(75) Inventors: Donald J.K. OLGADO, Palo Alto, CA (US); Tuan Anh (Mike) Nguyen, Santa Clara, CA (US); Alain Duboust, Sunnyvale, CA (US)

(73) Assignee: Applied Materials, Inc., Santa Clara, CA (US)

(21) Appl. No.: 13/282,914

(22) Filed: Oct. 27, 2011

Related U.S. Application Data
(60) Provisional application No. 61/407,853, filed on Oct. 28, 2010.

(51) Int. Cl. H01L 21/26; F27D 11/12

(52) U.S. Cl. 438/795; 392/411; 257/E21.328

(57) ABSTRACT

Embodiments of the present invention generally relate to an apparatus and methods for uniformly heating substrates in a processing chamber. In one embodiment, an apparatus generally includes a substrate supporting structure that is able to help minimize the temperature variation across each of the substrates during thermal processing. In one configuration, a substrate supporting structure is adapted to selectively support a substrate carrier to control the heat lost from regions of each of the substrates disposed on the substrate carrier. The substrate supporting structure is thus configured to provide a uniform temperature profile across each of the plurality of substrates during processing.

### CROSS-REFERENCE TO RELATED APPLICATIONS

This application claims benefit of U.S. provisional patent application Ser. No. 61/407,853 [Atty. Dkt. No. APPM 15757L], filed Oct. 28, 2010, which is herein incorporated by reference.

### BACKGROUND OF THE INVENTION

1. Field of the Invention

Embodiments of the present invention generally relate to methods and apparatus for uniformly heating substrates during high temperature processing.

2. Description of the Related Art

Advancements in reliably and consistently forming compound semiconductor layers (e.g., gallium nitride or gallium arsenide layers) that have uniform properties holds much promise for a wide range of applications in the electronics field (e.g., high frequency, high power devices and circuits) and the optoelectronics field (e.g., lasers, light-emitting diodes and solid state lighting). Generally, compound semiconductors are formed by high temperature thermal processes, such as heteroepitaxial growth on a substrate material. The thermal uniformity of the substrate during processing is important, since the epitaxial layer composition, and thus LED emission wavelength and output intensity, are a strong function of the surface temperature of the substrate. Moreover, since the compound semiconductor deposition and thermal processing temperatures are often in excess of 800° C., the control of the temperature in the processing chamber becomes much more difficult due to the difference in temperature between the heated substrate(s) and the much cooler processing chamber boundaries or walls. The processing chamber boundaries, or walls, are often maintained at temperatures less than about 200° C. to reliably provide a sealed processing region and for human safety reasons.

Due to the often long processing times (e.g., 1-24 hours) commonly required to form the compound semiconductor layers used in an LED devices, it is often desirable to process substrates in batches of two or more substrates at a time. During batch processing, the substrates are positioned on a supporting structure that is used to support and retain the substrates. However, the ability to control the temperature uniformity from substrate to substrate, and within each substrate, becomes much more difficult in batch configurations. The center to edge temperature variations commonly found in conventional processing chambers, due to the presence of the cooler processing chamber boundaries near the heated substrates, are generally too high to meet the current process yield goals. Variations in the substrate surface temperature will affect the growth rate of the formed compound semiconductor layer(s) causing them to be non-uniform across the substrate surface. In extreme cases, the substrate can bow enough to crack or break, thus damaging or ruining the compound semiconductor layers grown thereon.

Therefore, there is a need for apparatuses and methods that can provide a more uniform temperature profile across all of the substrates disposed in a batch processing chamber.

### SUMMARY OF THE INVENTION

One embodiment of the present invention generally provides an apparatus for thermally processing a substrate, comprising a carrier support having a central axis and a supporting feature, wherein the supporting feature has a support outer edge and a support inner edge, a substrate carrier disposed on the supporting feature, and having a carrier outer edge, and one or more lamps positioned to deliver electromagnetic energy to the carrier support and to the substrate carrier, wherein the support outer edge is a greater distance from the central axis than the carrier outer edge.

An embodiment of the present invention may further provide an apparatus for thermally processing a substrate, comprising a carrier support having a central axis and a supporting feature, a substrate carrier disposed on the supporting feature, and having a carrier outer edge, a carrier ring disposed on the substrate carrier, and having a ring inner edge, a ring outer edge and a body portion disposed between the ring inner edge and the ring outer edge, wherein the carrier outer edge is a greater distance from the central axis than the ring inner edge, and the ring outer edge is a greater distance from the central axis than the carrier outer edge, and one or more lamps positioned to deliver electromagnetic energy to the carrier support, the body portion of the carrier ring and the substrate carrier.

Embodiment of the present invention may further provide an apparatus for thermally processing a substrate, comprising a carrier support having a first surface that has a first emissivity, a second surface that has a second emissivity, an inner region for supporting a substrate carrier and an outer region that extends a desired distance beyond an outer edge of the substrate carrier, and one or more lamps positioned to deliver electromagnetic energy to the carrier support and to the substrate carrier, wherein the first surface of the carrier support is in the line-of-sight of the one or more lamps, the second surface of the carrier support is not in line-of-sight of the one or more lamps, and the first emissivity is greater than the second emissivity.

Embodiment of the present invention may further provide an apparatus for thermally processing a substrate, comprising a carrier support having a central axis and a supporting feature, a substrate carrier disposed on the supporting feature, and having a carrier outer edge, and one or more lamps positioned to deliver electromagnetic energy to the carrier support and to the substrate carrier, wherein the distance from an edge of a substrate disposed on the substrate carrier to the carrier outer edge is equal to or greater than 25% of the substrate diameter, wherein the edge of the substrate is the farthest point on the edge of the substrate from the central axis.

Embodiment of the present invention may further provide an apparatus for thermally processing a substrate, comprising a carrier support having a central axis, a supporting feature and an edge region, a substrate carrier disposed on the supporting feature, and having a carrier outer edge, wherein the edge region of the carrier support is disposed between the carrier outer edge and a wall of the apparatus, and one or more lamps positioned to deliver electromagnetic energy to the carrier support and to the substrate carrier, wherein the support outer edge is a greater distance from the central axis than the carrier outer edge.

Embodiment of the present invention may further provide a method of growing an epitaxial material on a substrate, comprising positioning a substrate carrier having a plurality of substrates disposed thereon on a carrier support disposed in a processing volume of a processing chamber, rotating the substrate carrier and the carrier support about a central axis, and delivering energy to the substrate carrier and the carrier support, wherein an outer edge of the carrier support is a greater distance from the central axis than an outer edge the substrate carrier.

Embodiment of the present invention may further provide a method of growing an epitaxial material on a substrate, comprising positioning the substrate carrier having a plurality of substrates disposed thereon on a carrier support disposed in a processing volume of a processing chamber, disposing a carrier ring on the substrate carrier; wherein a region of a body portion of the carrier ring extends over a region of the substrate carrier near an outer edge, rotating the substrate carrier, the carrier support and the carrier ring about a central axis, and delivering energy to the substrate carrier, the carrier support and the carrier ring.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a processing chamber for fabricating compound nitride semiconductor devices according to one or more embodiments described herein.

FIG. 2 is a schematic cross-sectional view of a substrate carrier and substrates that have a formed temperature profile created during processing in a processing chamber according to one or more embodiments described herein.

FIG. 3A is a bottom view of a substrate support assembly according to one or more embodiments described herein.

FIG. 3B is a schematic side cross-sectional view of a portion of the substrate support assembly shown in FIG. 3A according to one or more embodiments described herein.

FIG. 4 is a schematic side cross-sectional view of a portion of a substrate support assembly according to one or more embodiments described herein.

FIG. 5 is a schematic side cross-sectional view of a portion of a substrate support assembly according to one or more embodiments described herein.

FIG. 6 is a schematic side cross-sectional view of a portion of a substrate support assembly according to one or more embodiments described herein.

FIG. 7 is a schematic side cross-sectional view of a portion of a substrate support assembly according to one or more embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to an apparatus and methods for uniformly heating substrates in a processing chamber. In one embodiment, an apparatus generally includes a substrate supporting structure that is configured to minimize the temperature variation across each of the substrates during thermal processing. In one configuration, a substrate supporting structure is adapted to selectively support a substrate carrier to control the heat lost from regions of each of the substrates disposed on the substrate carrier. The substrate supporting structure is thus configured to provide a uniform temperature profile across each of the plurality of substrates during processing. In general, processing chambers that may benefit from one or more of the embodiments described herein include chambers that are able to perform high temperature thermal processes, such as chemical vapor deposition (CVD), hydride vapor phase epitaxy (HVPE) deposition or other thermal processes used to form or process light emitting diode (LED) and laser diode (LD) devices.

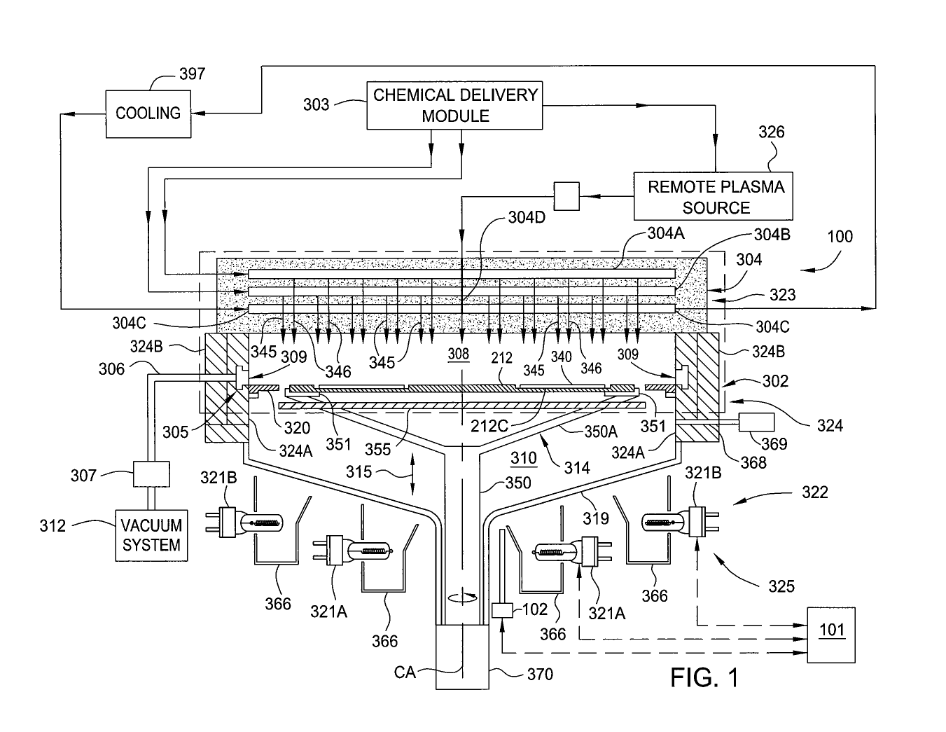

An example of a thermal processing chamber that may benefit from one or more the embodiments described herein is a metal oxide chemical vapor deposition (MOCVD) deposition chamber, which is illustrated in FIG. 1 and is further described below. While the discussion below primarily describes one or more of the embodiments of the present invention being disposed in a MOCVD chamber, this processing chamber type is not intended to be limiting as to the scope of the invention described herein. For example, the processing chamber may be an HVPE deposition chamber that is available from Applied Materials Inc. of Santa Clara, Calif. An example of an exemplary HVPE deposition chamber is further described in the commonly assigned U.S. patent application Ser. No. 12/637,019 [Atty. Docket No. APPM 14243], filed Dec. 14, 2009, which is incorporated by reference herein.

FIG. 1 is a schematic side cross-sectional view of a processing chamber 100 according to one or more embodiments described herein. In one example, as illustrated in FIG. 1, the processing chamber 100 is a metal oxide chemical vapor deposition (MOCVD) deposition chamber. The process chamber 100 may comprise a chamber body 302, a chemical delivery module 303 for delivering process gases, a substrate support assembly 314, an energy source 322 and a vacuum system 312. The process chamber 100 includes a chamber body 302 that encloses a processing volume 308, and generally includes a lid assembly 323, lower chamber assembly 325 and chamber support structure 324. In this case, the lid assembly 323 is disposed at one end of the processing volume 308, and the substrate carrier 212 is disposed at the other end of the processing volume 308.

The substrate carrier 212 may be disposed on the substrate support assembly 314, and is generally adapted to support and retain one or more substrates 340 on a substrate receiving surface 212C during processing in the processing chamber 100. The substrate carrier 212 is generally designed to damp the spatial variation in the amount of energy delivered from the energy source 322 to the substrates 340 and thus help provide a uniform temperature profile across the each of the substrates 340 disposed on the substrate carrier 212. The substrate carrier 212 is also designed to provide a steady support to each substrate 340 during processing. The substrate carrier 212 generally comprises a material that is able to with stand the high processing temperatures (e.g., >800° C.) used to process substrates in the processing volume 308 of the processing chamber 100. The substrate carrier 212 also generally comprises a material that has good thermal properties, such as a good thermal conductivity. The substrate carrier 212 will also have physical properties similar to the substrates 340, such as have a similar coefficient of thermal expansion, to avoid unnecessary relative motion between the surface of the substrate carrier 212 and the substrates 340 during heating and/or cooling. In one example, the substrate carrier 212 may comprise silicon carbide, or a graphite core that has a silicon carbide (SiC) coating formed by a CVD process over the core. The substrate carrier 212 may have a thickness of between about 0.06 inch (1.5 mm) to about 0.12 inch (3.0 mm). In one configuration, the substrates may be disposed in a recess formed in the substrate carrier 212 that is between about 0.005 inch (0.13 mm) to about 0.02 inch (0.5 mm) deep.

In one embodiment of the processing chamber 100, the lid assembly 323 comprises a showerhead assembly 304 that may include multiple gas delivery channels that are each configured to uniformly deliver one or more processing gases to the substrates disposed in the processing volume 308. In one configuration, the showerhead assembly 304 includes a first processing gas channel 304A coupled with the chemical delivery module 303 for delivering a first precursor or first process gas mixture to the processing volume 308, a second processing gas channel 304B coupled with the chemical delivery module 303 for delivering a second precursor or second process gas mixture to the processing volume 308 and a temperature control channel 304C coupled with a heat exchanging system 397 for flowing a heat exchanging fluid to the showerhead assembly 304 to help regulate the temperature of the showerhead assembly 304. In one example, it is desirable to regulate the temperature of the showerhead and surfaces exposed to the processing volume to temperatures less than about 200° C. at substrate processing temperatures between about 800° C. and about 1300° C. In one embodiment, during processing the first precursor or first process gas mixture may be delivered to the processing volume 308 via gas conduits 346 coupled with the first processing gas channel 304A in the showerhead assembly 304 and the second precursor or second process gas mixture may be delivered to the processing volume 308 via gas conduits 345, 346 coupled with the second gas processing channel 304B. In some configurations, a remote plasma source 326 is adapted to deliver gas ions or gas radicals to the processing volume 308 via conduit 304D formed in the showerhead assembly 304. It should be noted that the process gas mixtures or precursors may comprise one or more precursor gases or process gases as well as carrier gases and dopant gases which may be mixed with the precursor gases. Exemplary showerheads that may be adapted to practice embodiments described herein are described in U.S. patent application Ser. No. 12/870,465 [Atty. Dkt. No. APPM 12242.02 US], filed Sep. 29, 2010, which is herein incorporated by reference in its entirety.

The lower chamber assembly 325 generally includes a lower dome 319, an energy source 322 disposed adjacent to the lower dome 319, and a substrate support assembly 314. The lower dome 319 is disposed at one end of a lower volume 310, and the substrate carrier 212 is disposed at the other end of the lower volume 310. The substrate carrier 212 is shown in the process position, but may be moved to a lower position where, for example, the substrates 340 and/or substrate carrier 212 may be loaded or unloaded. An exhaust ring assembly 320 may be disposed around the periphery of the substrate carrier 212 to help prevent deposition from occurring in the lower volume 310 and also help direct exhaust gases from the chamber 100 to exhaust ports 309. The lower dome 319 may be made of transparent material, such as high-purity quartz, to allow energy (e.g., light) delivered from the energy source 322 to pass through for radiant heating of the substrates 340. The radiant heating provided from the energy source 322 may be provided by a plurality of inner lamps 321A and outer lamps 321B disposed below the lower dome 319. Reflectors 366 may be used to help control the processing chamber 100 exposure to the radiant energy provided by inner and outer lamps 321A, 321B. Additional rings of lamps may also be used for finer temperature control of the substrates 340.

In certain embodiments, a purge gas (e.g., a nitrogen containing gas) may be delivered into the processing chamber 100 from the showerhead assembly 304 and/or from inlet ports 368 coupled to a gas source 369 that are disposed below the substrate carrier 212 and near the bottom of the chamber body 302. The purge gas enters the lower volume 310 of the chamber 100 and flows upwards past the substrate carrier 212 and exhaust ring assembly 320 and into multiple exhaust ports 309 which are disposed around an annular exhaust channel 305. An exhaust conduit 306 connects the annular exhaust channel 305 to a vacuum system 312, which includes a vacuum pump 307. The chamber 100 pressure may be controlled using a valve system which controls the rate at which the exhaust gases are drawn from the annular exhaust channel. Other aspects of the MOCVD chamber are described in U.S. patent application Ser. No. 12/023,520, filed Jan. 31, 2008, published as US 2009-0194024, and titled CVD APPARATUS, which is herein incorporated by reference in its entirety. In some configurations of the processing chamber 100, an optional baffle plate 355 is disposed between the substrates 340 and the energy source 322 to prevent the interaction of the purge gas delivered into the lower volume 310 from inlet ports 368 and the substrate carrier 212, and to also help dampen the thermal variation created by the non-uniform distribution of lamps 321A-321B below the substrate carrier 212.

The chamber support structure 324 generally includes one or more walls, such as the inner wall 324A and/or outer wall 324B, that are configured to support the lid assembly 323 and lower chamber assembly 325. One or more of the walls generally comprises a metal sheet or plate that may act as the structural support and vacuum sealing surface that is attached to an external support structure, for example, a chamber position in a Centura™ cluster tool (not shown) available from Applied Materials Incorporated. The chamber support structure 324 is used in combination with the lid assembly 323 and lower chamber assembly 325 to enclose the processing volume 308 and lower volume 310. In an effort to assure that the high processing temperatures often used to process the substrates will not affect the external support structure and other adjacent components, the temperature of the walls of the processing chamber 100 and surrounding structures is controlled by circulating a heat-exchange liquid through channels (not shown) formed in one or more of the walls of the processing chamber. The heat-exchange liquid can be used to heat or cool the chamber walls depending on the desired effect. For example, a cool liquid may be used to remove heat from the processing chamber during processing to limit formation of deposition products on the walls, and/or for personnel safety reasons. Typically, the one or more walls are maintained at temperatures less than about 200° C., while the substrate are being processed at temperatures between about 800° C. and about 1300° C. In some configurations, the chamber support structure 324 includes an inner wall 324A that is formed from a thermally insulative material, such as a ceramic material, and the outer wall 324B is formed from a metal, such as stainless steel or aluminum.

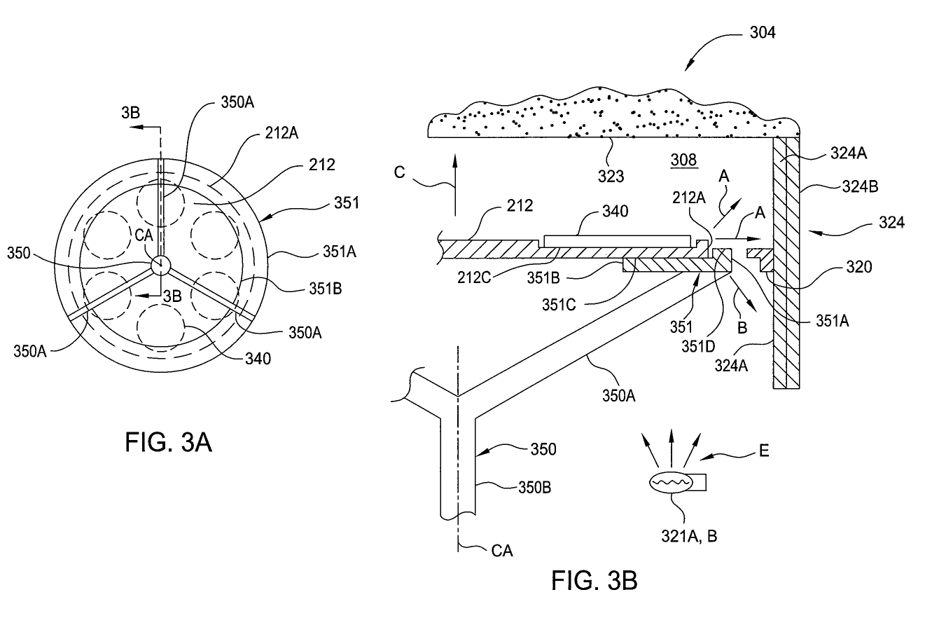

The substrate support assembly 314 is generally configured to support and retain the substrate carrier 212 during processing, and may include a carrier support 350 that has a plurality of angled supports 350A on which the substrate carrier supporting features 351 are disposed, as illustrated in FIGS. 3A-3B. FIG. 3A is bottom view of the substrate support assembly 314 shown in FIG. 1, and illustrates one possible configuration of the angled supports 350A and supporting feature 351 that are configured to support a substrate carrier 212 and substrates 340. FIG. 3B is a side cross-sectional view of a portion of the substrate support assembly 314 formed by sectioning the substrate support assembly 314 along a sectioning line 3B-3B shown in FIG. 3A. The substrate support assembly 314 generally includes an actuator assembly 370, which may include one or more electric motors, that is configured to provide z-lift capability and rotate the carrier support 350 and substrates 340 about a central axis “CA” during processing (e.g., 5-100 rpm). The z-lift capability is provided to allow the movement of the substrate carrier 212 in a vertical direction, as shown by arrow 315 (FIG. 1). In one embodiment, the z-lift capability may be used to move the carrier support 350 either upward and closer to the showerhead assembly 304 or downward and further away from the showerhead assembly 304. In certain embodiments, the substrate support assembly 314 comprises a heating element, for example, a resistive heating element assembly (not shown), such as a resistive elements embedded in a conductive block, that is configured to support and/or transfer heat to the substrate carrier 212 to control the temperature of the substrate support assembly 314 and consequently controlling the temperature of the substrate carrier 212 and substrates 340 positioned on the substrate support assembly 314. In general, the cross-section of the angled supports 350A are sized to minimize the amount of heat that is conducted away from the processing volume 308 to the lower chamber assembly 325 components, such as the actuator assembly 370. In one example, the angled supports 350A and shaft 350B of the carrier support 350 are formed from an insulating material, such as quartz, to reduce the amount of heat conduction to the lower chamber assembly 325 components.

Referring to FIG. 3B, during processing the electromagnetic energy “E” emitted from the energy delivery components (e.g., lamps 321A, 312B) found in the energy source 322 is delivered to the substrates 340 to achieve a desired temperature during processing. The temperature of the substrates is maintained at a desired processing temperature using a closed-loop control system. The closed-loop control system generally comprises a system controller 101 (e.g., conventional industrial computer/controller) and temperature probe 102 (e.g., pyrometer) that are used to control and directly, or indirectly, monitor the temperature of the substrates by controlling the energy delivered from the energy source 322.

During processing, a portion of the electromagnetic energy delivered from components in the energy source 322, such as lamps 321A, 321B, is received by the backside surface of the carrier 212 and supporting features 351. The received energy is then conducted to the substrates 340, which are disposed on the front surface found on an opposite side of the substrate carrier 212. When the substrate temperatures during processing are stable, a thermal equilibrium is achieved in the processing volume 308. At thermal equilibrium, or quasi-thermal equilibrium, an energy balance is maintained, such that all of the energy received by the substrate carrier 212, substrates 340 and carrier support 350 is then retransmitted or redistributed to other components in the processing chamber. Due to the high processing temperatures commonly used to form compound semiconductor layers and/or thermally process layers in a light emitting diode and laser diode processing sequence (e.g., 800° C. and 1300° C.) the proximity of portions of the substrates to the cooled or lower temperature chamber components can have a dramatic effect on the uniformity of the temperature measured across each of the substrates processed in the processing volume 308. Due to chamber size limitations, safety related issues and system cost concerns it is generally not possible to eliminate the negative temperature profile affects that the cooler chamber components have on the substrates during high temperature processing. It has been found, as illustrated in FIG. 3B, that the energy “A” flowing from the carrier outer edge 212A of the substrate carrier 212 and the energy “B” flowing from the adjacent supporting features 351 is generally higher than the energy “C” that flows from the center region of the substrate carrier 212, which creates a non-uniform temperature profile across the substrate carrier 212 and substrates 340.

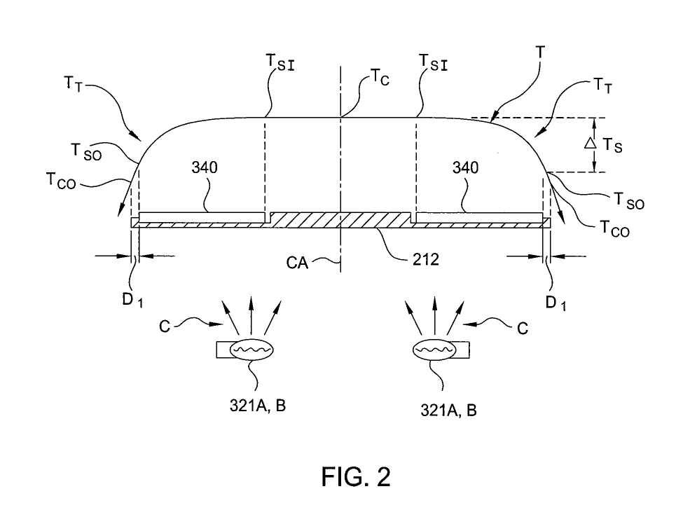

FIG. 2 is a side cross-sectional view of a substrate carrier 212 that illustrates a non-uniform temperature profile “T” schematically disposed above the substrate carrier to highlight the effect of the difference in heat lost from the center of the substrate carrier 212, which is maintained during processing at a temperature “T_{c}”, and the carrier outer edge 212A of the substrate carrier 212 that achieves a temperature “T_{co}”. Due to the position of the substrates 340 on the substrate carrier 212, portions of the substrate near the carrier outer edge 212A will have a temperature “Tₛₒ” and a portion of the substrate near the center of the carrier will have a temperature “Tₛᵢ”, which leads to a temperature variation “ΔTₛ” across the substrate. One will note that the temperature variation may be primarily caused by the edge temperature drop-off “T_{T}” created by the difference in the ability of regions of the substrate carrier and substrates to transfer heat to the surrounding environment. It is common for device manufacturers require the temperature variation to be less than about +/−2.5° C., which is very hard to achieve using conventional support structures. Due to a desire to minimize the process chamber size and substrate carrier 212 cost, it is common for the distance D₁ formed between the edge of the substrates 340 and the outer edge 212A of the substrate carrier 212 to be as small as possible, such as about 3-5 mm.

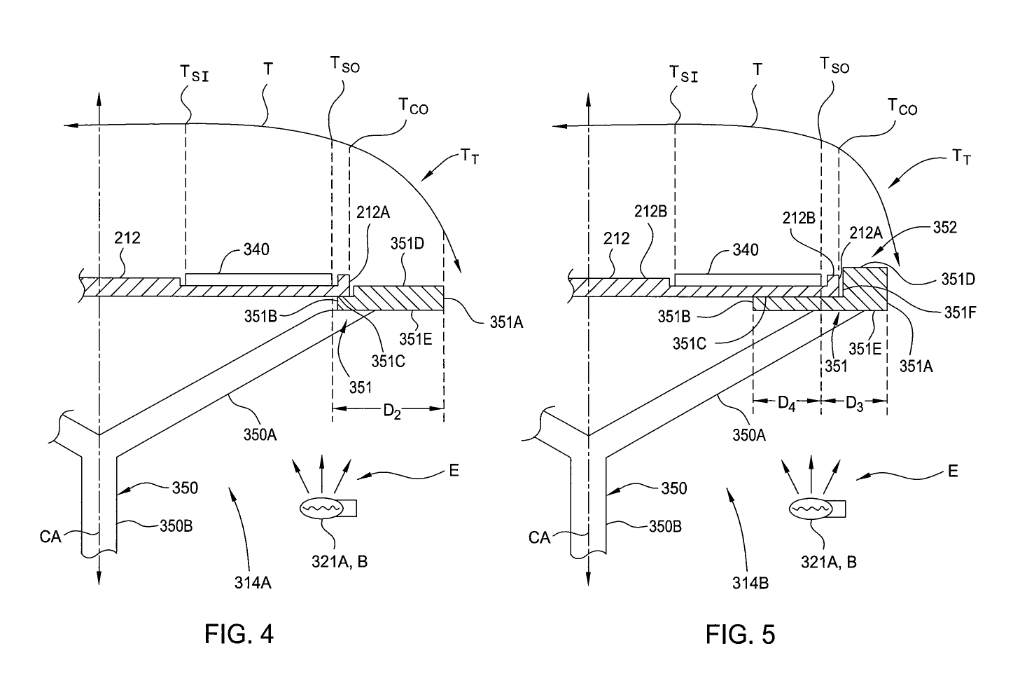

In an effort to resolve the typical thermal uniformity issues found in conventional processing configurations, embodiments of the present invention generally provide for the reconfiguration of the substrate support assembly 314 to minimize the affect of the surrounding lower temperature chamber components on the heated substrates. By reconfiguring the substrate support assembly 314, the temperature uniformity of the substrates during thermal processing can be greatly improved. FIGS. 4-7 are side cross-sectional views of a desirably configured substrate support assembly according one or more the embodiments described herein. In these figures the shape of the supporting feature 351 and support assembly hardware has been configured to reduce the non-uniformity typically experienced by conventional chamber designs during high temperature processing.

Therefore, in one embodiment, as illustrated in FIG. 4, the supporting feature 351 shape has been adjusted to reduce the negative affect caused by the position of the cooler chamber walls, or the “edge effect”. In this configuration the outer surface 351A of the supporting feature 351 has been formed a distance D₂ from the edge of each of the substrates 340, thus moving the edge temperature drop-off “T_{T}” a distance from the edge of the substrates 340. In some configurations, the substrate carrier 212 and supporting feature 351 are symmetric about a central axis “CA” of the carrier support 350, which is also generally the substrate support assembly's rotational axis, and thus the distance D₂ is measured from the outermost edge of the substrates along a radial direction extending from the central axis “CA”. The distance D₂ may be greater than about 25% of the substrate 340 diameter, but the desirable distance will generally vary due to the spacing between the outer surface 351A and the walls, and the surface temperature of the walls and the processing temperature of the substrates. For example, for 100 mm substrate the distance D₂ may be greater than about 25 mm.

Also, in some configurations of the substrate support assembly (e.g. reference numeral 314A in FIG. 4), the inner surface 351B of the supporting feature 351 is formed so that it minimally interferes with the energy “E” delivered from the lamps 321A, while also allowing the substrate carrier 212 to be reliably positioned on the supporting feature 351 by an external robot (not shown) during the insertion of the substrate carrier 212 in the processing chamber 100. The supporting feature 351 may be formed from a material that has similar optical and thermal properties as the substrate carrier 212. In one example, the supporting feature 351 is formed from a solid silicon carbide material, or a silicon carbide coated graphite material.

In another embodiment, as illustrated in FIG. 5, the shape of the supporting feature 351 in a substrate support assembly 314B has been altered so that the mass and shape of the edge region 352 damps and exchanges heat with the outer edge of each of the substrates 340, thus altering the shape of the edge temperature drop-off “T_{T}” so that the temperature at the edge temperature Tₛₒ of the substrates 340 is not affected by the edge temperature drop-off “T_{T}”. In this configuration the outer surface 351A of the supporting feature 351 has been formed a distance D₃ from the edge of each of the substrates 340, thus the physical position of the edge region 352 between the substrate carrier outer edge 212A and the walls 324A, 324B, and the added thermal mass of the edge region 352, alters the shape of the edge temperature drop-off “T_{T}” so that the temperature variation “ΔTₛ” is minimized. It is believed that by positioning the edge region 352 of the supporting feature 351 between the outer edge 212A of the substrate carrier 212 and the walls 324A, 324B the amount of radiant heat loss from the edge of the substrate carrier 212 and substrates 340 can be reduced, thus minimizing the affect of the edge temperature drop-off “T_{T}” on the substrates during processing. The distance D₃ may be greater than about 10% of the substrate 340 diameter, however, the distance D₃ will vary due to the spacing between the outer surface 351A and the walls, the mass and shape of the edge region 352, and the surface temperature of the walls.

In some configurations of the substrate support assembly, the inner surface 351B of the supporting feature 351 is formed so that it overlaps a distance D₄ with the edge of the substrate 340 to retain a desired amount of the energy delivered from the lamps 321A, 321B to alter the edge temperature drop-off “T_{T}” to reduce the temperature difference across the substrates 340. The distance D₄ may be between about 1 mm and 10 mm. In this configuration, the supporting feature 351 may be formed from a material that has similar optical and thermal properties as the substrate carrier 212, and also has a desirable heat capacity. In some configurations, the distances D₃ and D₄ can be measured from the outermost edge of the substrates along a radial direction extending from the central axis “CA”.

In some configurations of the supporting feature 351, a high emissivity coating or surface finish may be formed on the lower surface 351E of the supporting feature 351 to absorb a large portion of the energy “E” delivered from the lamps 321A, 321B, while a lower emissivity coating or surface finish may be disposed on the surfaces 351A and 351D to reduce the radiation to the walls. In one configuration, the surface 351D is disposed above the top surface 212B of the substrate carrier 212, which is disposed on the surface 351C of the supporting feature 351. Therefore, in one configuration, the lower surface 351E, which is in the line-of-sight of the electromagnetic energy “E” delivered from the lamps 321 A,B, will tend to absorb a large amount of the delivered energy, while the surfaces 351A, 351C, 351D and/or 351F, which are generally not in the line-of-sight of the electromagnetic energy “E” emitted from the lamps 321A,B, will tend to radiate energy at a lower rate. In this case, when the chamber is at steady state during processing, the supporting feature 351 may reach a higher temperature than the substrate carrier and, thus, compensate for any thermal non-uniformity across the substrate carrier. In one example, the supporting feature 351 is formed from a refractory metal, solid silicon carbide material, or a silicon carbide coated graphite material.

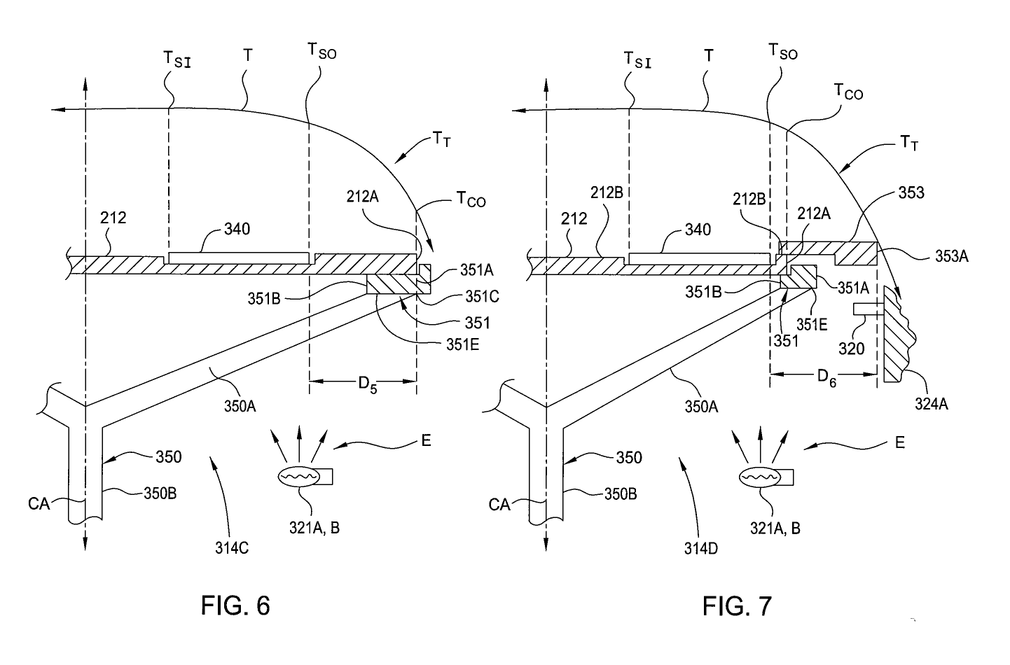

In another embodiment, as illustrated in FIG. 6, the outer edge 212A of the substrate carrier 212 is extended a distance from the edge of the substrates 340 to reduce the negative affects caused by the relative position of an edge region of the substrates to the cooler chamber walls. In this configuration, the outer edge 212A of the substrate carrier 212 is disposed a distance D₅ from the edge of each of the substrates 340, thus moving the edge temperature drop-off “T_{T}” a distance from the edge of the substrates 340. The distance D₅ may be greater than about 25% of the substrate 340 diameter, but the desirable distance will generally vary due to the spacing between the outer edge 212A and the walls, the surface temperature of the walls and the processing temperature of the substrates. In one example, the distance D₅ is between about 15 mm and about 20 mm. In one configuration, the inner surface 351B of the supporting feature 351 of the substrate support assembly 314C, which is configured to support the substrate carrier 212, is formed so that it minimally interferes with the energy delivered from the lamps 321A, 321B to the substrates 340, while also allowing the substrate carrier 212 to be reliably positioned on the supporting feature 351 by an external robot (not shown).

In another embodiment, as illustrated in FIG. 7, an annular carrier ring 353 having a desirable annular shape is used to reduce the negative affect caused by the position of the cooler chamber walls relative to an edge region of the substrates 340. The annular carrier ring 353 is disposed on the outer edge of the substrate carrier 212 during processing and is configured to receive a portion of the energy emitted from the energy source 322 to cause the edge temperature drop-off “T_{T}” to occur a desired distance from the edge of the substrates 340. The annular carrier ring 353 may be configured in an annular shaped body 353C that is symmetric about an axis (e.g., axis “CA”), such that a ring inner edge 353B is positioned at a diameter that is smaller than the diameter of the substrate carrier 212 and a ring outer edge 353A that is formed a distance D₆ from the edge of each of the substrates 340. The distance D₆ may be greater than about 25% of the substrate 340 diameter, but the desirable distance will generally vary due to the spacing between the ring outer edge 353A and the walls, the surface temperature of the walls, and the processing temperature of the substrates. In one example, the distance D₆ is between about 15 mm and about 20 mm. When not in use, the annular carrier ring 353 may be configured to rest on the exhaust ring assembly 320 when the carrier support 350 is positioned in the lower volume 310. Therefore, when the carrier support 350 moves from the lower volume 310, after receiving a substrate carrier 212 from the external robot, the annular carrier ring 353 is picked up from the exhaust ring assembly 320 by the carrier support 350 and substrate carrier 212. The annular carrier ring 353 and supporting feature 351 may be formed from a material that has similar optical and thermal properties as the substrate carrier 212. In one example, the annular carrier ring 353 is formed from a solid silicon carbide material, or a silicon carbide coated graphite material. As illustrated in FIG. 7, in one embodiment, the outer surface 351A of the supporting feature 351 of the substrate support assembly 314D may also extend a desired distance beyond the outer edge 212A of the substrate carrier 212, and thus may also include some of the advantages discussed above in conjunction with FIG. 4.

As noted above, embodiments of the invention generally provide a substrate supporting structure that is configured to selectively support a substrate carrier to control the heat lost from various regions of each of the substrates disposed on the substrate carrier. The substrate supporting structure is thus configured to provide a uniform temperature profile across each of the plurality of substrates during the processing steps performed in a processing chamber. One will note that in some configurations of the processing chamber 100, one or more of the embodiments of the invention that are illustrated in FIGS. 4-7 may be combined to improve the thermal uniformity of the thermally processed substrates. In one example, the designs illustrated in FIGS. 4 and 7, FIGS. 5 and 7 and/or FIGS. 6 and 7 may be combined to improve the thermal uniformity of the thermally processed substrates.

While the foregoing is directed to embodiments of the present invention, other and further embodiments of the invention may be devised without departing from the basic scope thereof, and the scope thereof is determined by the claims that follow.

We claim:

1. An apparatus for thermally processing a substrate, comprising:
a carrier support having an inner region for supporting a substrate carrier and an outer region that extends a desired distance beyond an outer edge of the substrate carrier;
an annular carrier ring having an inner region that is supported by an edge region of the substrate carrier during processing and an outer region that extends a desired distance beyond an outer edge of the substrate carrier; and
one or more lamps positioned to deliver electromagnetic energy to the annular carrier ring and to the substrate carrier.

2. The apparatus of claim 1, wherein the substrate carrier, carrier support and annular carrier ring both comprise silicon carbide.

3. The apparatus of claim 1, wherein the distance from the outer edge of the substrate carrier to an outer edge of the annular carrier ring is equal to or greater than 25% of a diameter of a substrate disposed on a substrate receiving surface of the substrate carrier during processing.

4. The apparatus of claim 1, wherein the distance from an edge of a substrate disposed on a substrate receiving surface of the substrate carrier to the carrier outer edge is equal to or greater than 25% of the substrate diameter, wherein the edge of the substrate is the farthest point on the edge of the substrate from the central axis.

5. An apparatus for thermally processing a substrate, comprising:
a carrier support having a first surface that has a first emissivity, a second surface that has a second emissivity, an inner region for supporting a substrate carrier and an outer region that extends a desired distance beyond an outer edge of the substrate carrier; and
one or more lamps positioned to deliver electromagnetic energy to the carrier support and to the substrate carrier, wherein the first surface of the carrier support is in the line-of-sight of the one or more lamps, the second surface of the carrier support is not in line-of-sight of the one or more lamps, and the first emissivity is greater than the second emissivity.

6. The apparatus of claim 5, wherein the substrate carrier and carrier support both comprise silicon carbide.

7. The apparatus of claim 5, wherein the carrier support further comprises a carrier outer edge, and wherein the distance from the outer edge of the substrate carrier to the carrier outer edge is equal to or greater than 25% of a diameter of a substrate disposed on the substrate carrier.

8. The apparatus of claim 5, further comprising an annular carrier ring having an inner region that is disposed over a region of the substrate carrier during processing and an outer region that extends a desired distance beyond the outer edge of the substrate carrier.

9. An apparatus for thermally processing a substrate, comprising:
a carrier support having a central axis and a supporting feature;
a substrate carrier disposed on the supporting feature, and having a carrier outer edge;
a carrier ring disposed over the substrate carrier, and having a ring inner edge, a ring outer edge and a body portion disposed between the ring inner edge and the ring outer edge, wherein the carrier outer edge is a greater distance from the central axis than the ring inner edge, and the ring outer edge is a greater distance from the central axis than the carrier outer edge; and
one or more lamps positioned to deliver electromagnetic energy to the carrier support, the body portion of the carrier ring and the substrate carrier.

10. The apparatus of claim 9, wherein the substrate carrier and carrier ring are both comprise silicon carbide.

11. The apparatus of claim 9, wherein the distance from an edge of a substrate disposed on the substrate carrier to the ring outer edge is equal to or greater than 25% of the substrate diameter, wherein the edge of the substrate is the farthest point on the edge of the substrate from the central axis.

12. The apparatus of claim 9, wherein the distance from an edge of a substrate disposed on the substrate carrier to the carrier outer edge is equal to or greater than 25% of the substrate diameter, wherein the edge of the substrate is the farthest point on the edge of the substrate from the central axis.

13. The apparatus of claim 9, further comprising an actuator that is configured to rotate the carrier support about the central axis.

14. A method of growing an epitaxial material on a substrate, comprising:
positioning a substrate carrier having a plurality of substrates disposed thereon on a carrier support disposed in a processing volume of a processing chamber;
disposing an annular carrier ring on the substrate carrier; wherein a region of a body portion of the annular carrier ring extends over a region adjacent to an outer edge of the substrate carrier;
rotating the substrate carrier, annular carrier ring and the carrier support about a central axis; and
delivering energy to the substrate carrier and the carrier support, wherein an outer edge of the carrier support is a greater distance from the central axis than an outer edge the substrate carrier, and delivering energy comprises heating one or more substrates disposed on the substrate carrier to a temperature greater than about 800° C.

15. The method of claim 14, wherein the distance from an edge of a substrate disposed on the substrate carrier to an outer edge of the substrate carrier is equal to or greater than 25% of the substrate diameter, wherein the edge of the substrate is the farthest point on the edge of the substrate from the central axis.
